(19) United States
(12) Patent Application Publication
(10) Pub. No.: US 2024/0030208 A1
(43) Pub. Date: Jan. 25, 2024

(54) HETEROGENEOUS EMBEDDED POWER DEVICE PACKAGE USING DAM AND FILL

(71) Applicant: SEMICONDUCTOR COMPONENTS INDUSTRIES, LLC, Phoenix, AZ (US)

(72) Inventors: Shutesh KRISHNAN, Negeri Sembilan (MY); Chee Hiong CHEW, Seremban (MY)

(73) Assignee: SEMICONDUCTOR COMPONENTS INDUSTRIES, LLC, Phoenix, AZ (US)

(21) Appl. No.: 17/814,566

(22) Filed: Jul. 25, 2022

(51) Int. Cl. H01L 25/18; H01L 23/00; H01L 23/31; H01L 21/56

(52) U.S. Cl. CPC H01L 25/18; H01L 24/40; H01L 23/3107; H01L 24/48; H01L 24/73; H01L 24/32; H01L 21/56; H01L 24/92; H01L 2224/40227; H01L 2224/48135; H01L 2224/48225; H01L 2224/73221; H01L 2224/32245; H01L 2224/291; H01L 2924/014; H01L 24/29; H01L 2224/73265; H01L 2224/92157; H01L 2224/37147; H01L 24/37; H01L 2224/73263

(57) ABSTRACT

A package includes a dielectric fill material layer embedding a first semiconductor die, a connector clip, and a second semiconductor die. The connector clip has a segment disposed above the dielectric fill material layer embedding the first semiconductor die. This segment of the connector clip is aligned along a same direction as a top surface of the first semiconductor die. The second semiconductor die is disposed on the segment of the connector clip disposed above the dielectric fill material layer.

### TECHNICAL FIELD

This description relates to packaging of semiconductor die and integrated circuits.

### BACKGROUND

In many integrated circuit (IC) packages, semiconductor device die are situated on top of a substrate. The substrate serves as the bridge between the devices and a board in a system. In some packaging technologies, the semiconductor die are embedded within the substrate. With increasing demand for high-density, high-speed, high-performance ICs, new improvements are needed in packaging technologies to bring out the ICs' performance and shrink package size.

### SUMMARY

In a general aspect, a package includes a dielectric fill material layer embedding a first semiconductor die, a connector clip, and a second semiconductor die. The connector clip has a segment disposed above the dielectric fill material layer embedding the first semiconductor die. This segment of the connector clip is aligned along a same direction as a top surface of the first semiconductor die. The second semiconductor die is disposed on the segment of the connector clip disposed above the dielectric fill material layer.

In a general aspect, a package includes a first semiconductor die, a second semiconductor die, and a third semiconductor die. The second semiconductor die is disposed to a side of the first semiconductor die. The first semiconductor die, and the second semiconductor die are embedded in a first dielectric fill material layer. The package further includes a first connector clip having a segment overlaying a first portion the first dielectric fill material layer, and a second connector clip having a segment overlaying a second portion of the first dielectric fill material layer. The third semiconductor die is disposed on the segment of the first connector clip overlaying the first portion of the first dielectric fill material layer. The package further includes a second dielectric fill material layer overlaying the first dielectric fill material layer and embedding the third semiconductor die.

In a general aspect, a method for embedding semiconductor dies in an embedded device package includes attaching a first semiconductor die to a substrate and embedding the first semiconductor die in a dielectric fill material layer. The method further includes connecting a source pad of the first semiconductor die and a first connector pad on the substrate with a first connector clip. The first connector clip includes a segment extending from the source pad toward a portion of the substrate external to the dielectric fill material layer embedding the first semiconductor die.

In an aspect, the method includes disposing a second semiconductor die on the first connector clip above the first semiconductor die, disposing a third semiconductor die on the dielectric fill material layer, and connecting a source pad of the second semiconductor die to a second connector pad on the portion of the substrate external to the dielectric fill material layer with a second connector clip.

In a further aspect, method further includes wire bonding connection wires between the third semiconductor die and gate contact pads on the first semiconductor die and the second semiconductor die.

In a further aspect, the method include encapsulating components of the embedded device package in a molding material.

The details of one or more implementations are set forth in the accompanying drawings and the description below. Other features will be apparent from the description and drawings, and from the claims.

### BRIEF DESCRIPTION OF THE DRAWINGS

FIG. 1A illustrates an example arrangement of multiple semiconductor die that can be embedded in a device package.

FIGS. 1B and FIG. 1C illustrate a cross-sectional view and a top view, respectively, of an example embedded device package.

FIG. 2 illustrates an example reeled substrates frame including an array of substrates.

FIGS. 3A through 3C illustrate cross-sectional views of embedded device packages.

FIG. 4 illustrates an example method for embedding a semiconductor die in a package.

FIGS. 5A through 5H illustrate cross-sectional views of an embedded device package at different stages of construction.

FIG. 6 illustrates another example method for embedding a semiconductor die in a package.

FIGS. 7A through 7H illustrate cross-sectional views of another embedded device package at different stages of construction.

### DETAILED DESCRIPTION

For modern electronic circuit applications, a plurality of semiconductor die or integrated circuit (IC) chips (e.g., metal-oxide-semiconductor field-effect transistor (MOSFET), insulated-gate bipolar transistor (IGBT), high-side and low-side FET switches, driver or controller IC chips, etc.) may be embedded in a single device package. An example device package is traditionally constructed by using a lateral placement of the die components (e.g., MOSFETs, controller die (IC chips), etc.). For example, MOSFETs corresponding to high-side and low-side FET switches may be placed on a same plane in the device package and a controller die (IC chip) may be stacked on one of the MOSFETs. The lateral placement of the die can be problematic in some implementations in manufacturing and can use up significant area.

In the implementations described herein, wire bonding or clip connections may be used to electrically connect the embedded devices to printed traces of the substrate or to external leads of a leadframe integrated within device package. In the implementations described herein, a dam-and-fill technique is used to fully encapsulate a semiconductor die, for example, a wire bonded die in the device package. In the dam-and-fill technique, a high viscosity dielectric fill material (e.g., epoxy) is first dispensed around the periphery of the top of the component to form a dam (i.e., a wall), followed by filling (e.g., back filling) of the dam with a low viscosity dielectric fill material to embed the component.

In an example implementation, a device package (e.g., a power MOSFET, or a driver MOSFET package) may be constructed by using a lateral placement or a stacking of the die components (e.g., MOSFETs, controller IC chip) on a substrate. For example, two MOSFETs corresponding to high-side and low-side FET switches (i.e., HS FET and LS FET) may be placed on lateral planes on the substrate in the device package and a semiconductor die (i.e., a controller IC chip) may be stacked on one of the MOSFETs. The HS FET is usually smaller in size than a size of the LS FET.

The circuit application (of the device package) may require that the source of the HS FET should be electrically connected to drain of the LS FET drain. Therefore, the MOSFETS should be connected as close as possible to each other to reduce resistance and switching loss.

Vertical stacking of the MOSFETs (e.g., directly one on top of the other) in the device package may be disfavored due to the impact of vertical stacking on the electrical and thermal requirements of the device package. Further, because the HS FET is usually smaller than the LS FET, an alternate approach of placing the unequal size MOSFET in a flip chip configuration on the other MOSFET is also disfavored at least because of assembly risks and reliability risks. The implementations described herein address these issues and include a cost effective and reliable solution for embedding the MOSFETs in a stacked configuration in an embedded device package.

An embedded device package having a plurality of semiconductor die disposed on multiple planes at different vertical levels (i.e., at different heights) in the package, and methods and techniques for making the embedded device package, are disclosed herein, in accordance with the principles of the present disclosure. The semiconductor die in the package may be embedded in dielectric fill material layers (in other words, fixed firmly and deeply in the dielectric fill material layers). In some implementations, a semiconductor die embedded in a dielectric fill material layer (e.g., an epoxy layer) may not be fully covered by, or buried in, the dielectric fill material layer and may have portions (e.g., contact pads) exposed through the dielectric fill material layer in which the die is embedded. In some implementations, the semiconductor die embedded in the dielectric fill material layer (e.g., an epoxy layer) may be fully covered by, or buried in, the dielectric fill material layer.

The solutions described herein provide geometrical flexibility in embedding active dies (MOSFET, Logic, Analog, etc.) and passive device components in an embedded device package.

In the embedded device package, a source of a first semiconductor die disposed on a plane at a first vertical level may be electrically connected to a drain of a second semiconductor die disposed on a plane at a second vertical level. The semiconductor die may be disposed geometrically in the embedded device package in a manner that allows close electrical connection of the source of the first semiconductor die to the drain of a second semiconductor die (e.g., to reduce resistance and switching loss). In example implementations, the drain of a second semiconductor die may be placed vertically on top of the source of the source of the first semiconductor die.

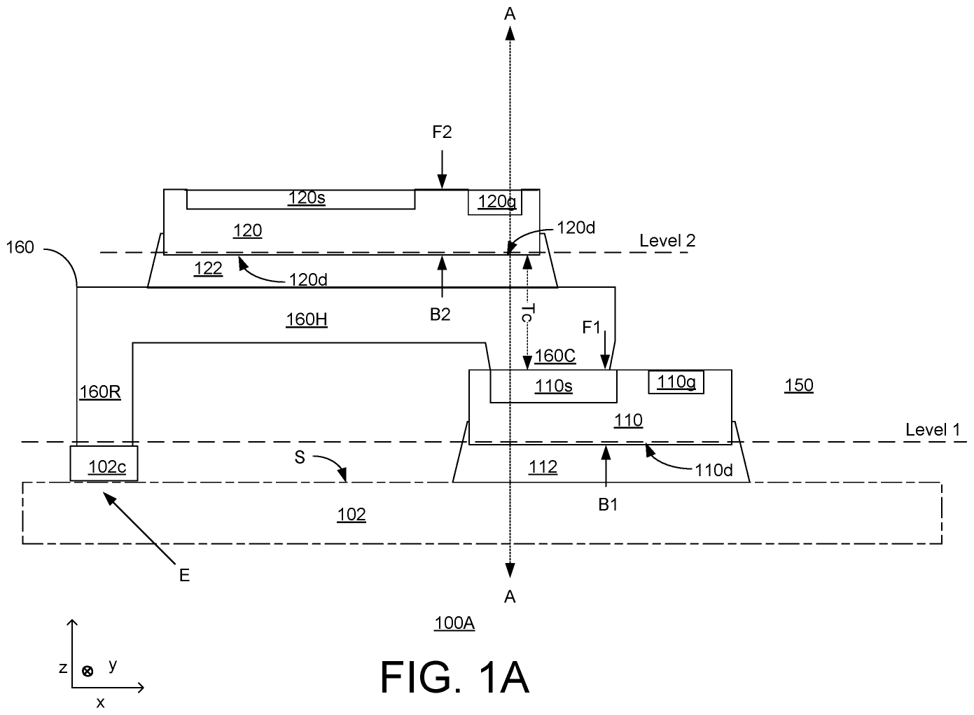

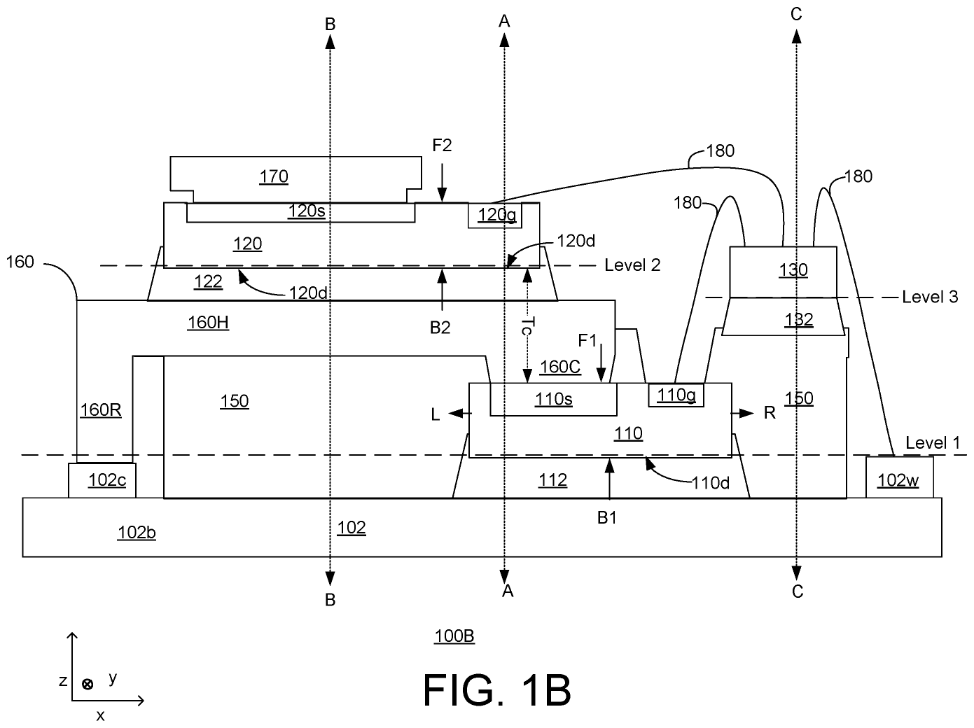

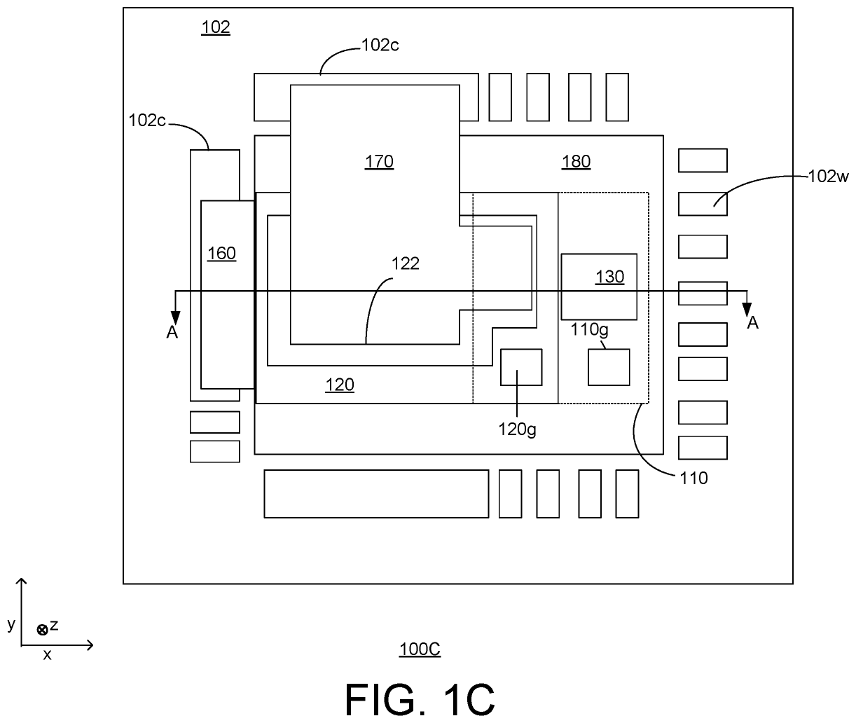

FIG. 1A illustrates an example arrangement 100A of multiple semiconductor die that can be embedded in a device package. In arrangement 10, the semiconductor die may be vertically stacked, one above the other, to provide, for example, a close or short electrical connection between the source of a first semiconductor die (e.g., HS FET die 110) to the drain of a second semiconductor die (e.g., a die 120).

In arrangement 100A, the dies may be stacked at vertical levels directly one on top of the other. For example, HS FET die 110 may be disposed on a removable substrate (e.g., substrate 102) at a first vertical level (e.g., Level 1) above a top surface S of a substrate 102, and die 120 may be disposed at second vertical level (e.g., Level 2) above top surface S of substrate 102.

HS FET die 110 can, for example, have a top or frontside surface F1 and a backside surface B 1. Frontside surface F1 and backside surface B1 of HS FET die 110, and top surface S of substrate 102 may be aligned with each other (e.g., be in x-y planes substantially parallel to each other).

HS FET die 110 can have a source pad 110s and a gate contact pad 110g on frontside surface F1, and a drain 110d on backside surface B1. Drain 110d on backside B1 may be attached to substrate 12 by a solder layer (e.g., solder layer 112). A conductive connector clip (e.g., connector clip 160) may be attached to HS FET die 110 to connect source pad 110s to a first connector pad (e.g., connector pad 102c) disposed, for example, at an edge portion E of substrate 102.

The conductive connector clip (e.g., connector clip 160) may include a vertical portion (e.g., riser 160R) that rises generally vertically (e.g., in the z direction) above connector pad 102c, and a horizontal or lateral segment (e.g., horizontal segment 160H) extending generally horizontally (laterally) (e.g., in the x-y plane) from the vertical portion (e.g., riser 160R) toward a pad contact element 160C. Pad contact element 160C may make mechanical or physical contact with the source pad (e.g., source pad 110s) of HS FET die 110 for electrical connection. In example implementations, connector clip 160 may be disposed in an orientation in which the horizontal or lateral segment (e.g., horizontal segment 160H) may be aligned along a same direction as substrate 102 (e.g., can be parallel to substrate 102, aligned along a top surface S of substrate 102).

Die 120 (disposed at vertical Level 2 above HS FET die 110) can have, for example, a source pad 120s and a gate contact pad 120g on a frontside surface F2 and a drain 120d on a backside surface B2. In arrangement 100A, to obtain a close or short electrical connection between source pad 110s of HS FET die 110 and drain 120d of die 120, die 120 may be disposed on connector clip 160 that is connected to the source pad (e.g., source pad 110s) of HS FET die 110. A solder layer 122 may be used to attach drain 120d of HS FET die 120 to connector clip 160. In example implementations, as shown in FIG. 1A, drain 120d of die 120 may be positioned directly above source pad (e.g., source pad 110s) of HS FET die 110 (e.g., along vertical axis A-A) separated only by a combined thickness Tc of connector clip 160 and solder layer 122. This positioning (i.e., vertical stacking) of the dies and the connector clip enables the close or short electrical connection between the source of the first semiconductor (e.g., HS FET die 110) and the drain of a second semiconductor die (e.g., die 120).

In example implementations, the embedded device package may be constructed on a substrate (e.g., a metal, ceramic, or polymer substrate, etc.). In example implementations, the substrate can be a printed circuit board (PCB) substrate with patterned conductive traces on at least one side of the substrate. The patterned conductive traces may include, for example, die attach pads, and copper pads for wire bonding or for clip connectors. In example implementations, the substrate with patterned conductive traces may, for example, be a land grid array (LGA) or a low-profile land grid array (LLGA) type of copper leadframe. In the embedded device package, the semiconductor die may be connected to each other, to other devices, or to the conductive traces on the substrate, with either a wire bond or conductive clip connector.

In example implementations, an embedded device package including a plurality of semiconductor die may have a first of the semiconductor die mounted on the substrate at a first vertical height or level (e.g., Level 1) (e.g., in the z direction) in the package. The first of the semiconductor die mounted on the substrate may be embedded in dielectric fill materials (using the dam-and-fill technique). The second and other semiconductor die (of the plurality of semiconductor die) may be disposed at other vertical heights or levels (e.g., Level 2, Level 3, etc.) on or above the vertical height (e.g., Level 1) of the dielectric fill materials embedding the first of the semiconductor die at the first level.

The plurality of semiconductor die that are vertically stacked (i.e., disposed at the different heights or levels) in the package may include dies of different sizes and of different device technology types (e.g., MOSFET, logic, analog, etc.). The dies may have sizes, for example, in a range of 0.5×0.5 mm to 20 mm×20 mm. Larger size die can be stacked on top of smaller size die. Semiconductor die at all vertical heights or levels (e.g., Level 1, Level 2, Level 3, etc.) may be interconnected using wire bonding and passive components. Use of bumping for interconnection of semiconductor die at any level can be avoided.

FIG. 1B shows a cross-sectional view (in an x-z plane) of an example embedded device package 100B including multiple semiconductor (device) die constructed on a substrate 102, in accordance with the principles of the present disclosure. FIG. 1C shows a top view (in an x-y plane) of another example embedded device package 100C constructed on substrate 102, in accordance with the principles of the present disclosure

Substrate 102 (in embedded device package 100B (FIG. 1B) and embedded device package 100C (FIG. 1C) may, for example, be a low-profile land grid array (LLGA) type copper leadframe. For example, substrate 102 may include patterned conductive traces and pads (including, for example, connector pad 102c, wire bond pad 102w, etc.) plated or formed on a base carrier portion 102b. Although a PCB substrate is described within many of the implementations, different types of substrates with a dielectric and traces can be used in place of a PCB substrate.

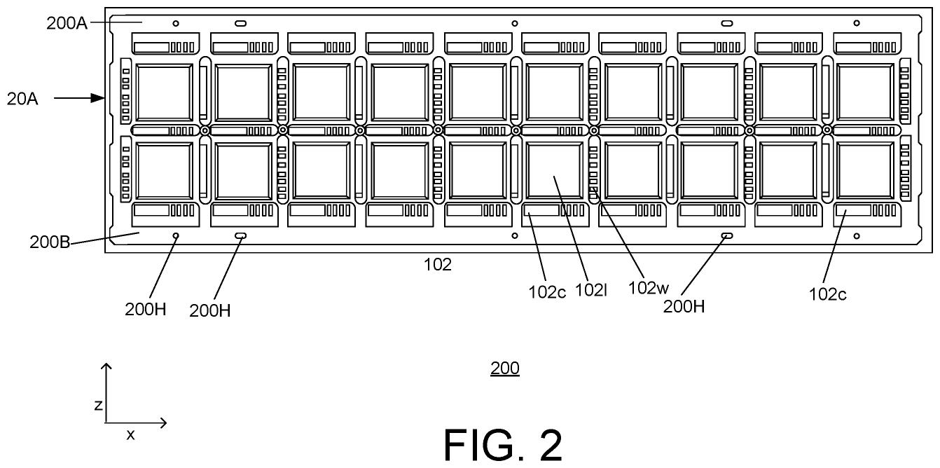

FIG. 2 (discussed later below herein) illustrates example substrate frames including LLGA type leadframes (e.g., substrate 102) and array of land grid array (LGA) type leadframes.

With reference to FIGS. 1B and 1C, in example implementations, the semiconductor die included in embedded device package 100B (or in embedded device package 100C) may, for example, include a HS FET die 110, a LS FET die 120 and another semiconductor die (e.g., an IC chip, controller chip 130). HS FET die 110 may include source and gate contact pads (e.g., source pad 110s and gate contact pad 110g) on a frontside surface (e.g., frontside surface F1), and a drain contact pad (e.g., 110d) on a backside surface (e.g., backside surface B1) of the die. LS FET die 120 may include source and gate contact pads (e.g., source pad 120s and gate contact pad 120g), for example, on a frontside surface (e.g., frontside surface F2) of the die, and a drain contact pad (e.g., 120d) on a backside surface (e.g., backside surface B2) of the die.

In embedded device package 100B (and in embedded device package 100C), HS FET die 110 and LS FET die 120 may be geometrically disposed at different vertical levels (heights) (in the z direction above substrate 102) in a manner that allows close electrical connection of source pad 110s of HS FET die 110 to drain 120d of LS FET die 120 (e.g., to reduce resistance and switching loss).

In an example implementation, a first of the semiconductor die (e.g., HS FET die 110) may be mounted on substrate 102 at a first vertical level (Level 1) in the z-direction. A solder layer 112 may be used to attach drain 110d of HS FET die 110 to substrate 102 (e.g., a PCB substrate) (e.g., on landing pad 102l, FIG. 2).

HS FET die 110 mounted on the substrate may be embedded in a layer of dielectric fill material (e.g., epoxy layer 150) deposited around HS FET die 110 on substrate 102. Epoxy layer 150 may be deposited on substrate 102, for example, by a dam-and-fill technique. Source and gate contact pads (e.g., source pad 110s and gate contact pad 110g) of HS FET die 110 may be left exposed through epoxy layer 150 (e.g., for clip attach and wire bonding, respectively). In example implementations, epoxy layer 150 materials may be deposited on substrate 102 around HS FET die 110 by the dam-and-fill technique without dam-and-fill dielectric fill material deposition on the source and gate contact pads (e.g., source pad 110s and gate contact pad 110g) (in other words, leaving the source and gate contact pads uncovered and exposed though epoxy layer 150). In some example implementations, for smaller source or gate contact pad structures that may be covered by dam-and-fill dielectric fill material, the source and gate contact pads (e.g., source pad 110s and gate contact pad 110g)) may be exposed by drilling vias (e.g., using a laser) through the covering dam-and-fill dielectric fill material to expose the source and gate contact pads.

A conductive connector clip (e.g., connector clip 160) may be attached to HS FET die 110 to connect source pad (e.g., source pad 110s) of HS FET die 110 to a first connector pad (e.g., connector pad 102c) on substrate 102. The connector pad may be disposed external to epoxy layer 150 (e.g., to or on a side of the epoxy layer). Connector clip 160 may be made of copper or other metal alloy. Connector clip 160 may include vertical portion (e.g., riser 160R) that rises generally vertically (e.g., in the z direction) above connector pad 102c, and a horizontal or lateral segment (e.g., horizontal segment 160H) extending generally horizontally (laterally) (e.g., in the x-y plane) from the vertical portion (e.g., riser 160R) toward pad contact element 160C. Pad contact element 160C may make physical contact with the source pad (e.g., pad 110s) of HS FET die 110 for electrical connection. Connector clip 160 may be disposed so that the horizontal or lateral segment (e.g., horizontal segment 160H) is above, and rests on (lays on), a first portion of epoxy layer 150 (e.g., a portion disposed to a left side (e.g., side L) of HS FET die 110, as shown in FIG. 1B.

Further, a second of the semiconductor die (e.g., LS FET die 120) may be disposed at a second vertical level (Level 2) in the z- direction in embedded device package 100B. To obtain a geometrically close electrical connection of source pad 110s of HS FET die 110 to drain 120d of LS FET die 120, LS FET die 120 may be disposed on connector clip 160 (e.g., on horizontal segment 160H) that is connected to the source pad (e.g., source pad 110s) of HS FET die 110. A solder layer 122 may be used to attach drain 120d of LS FET die 120 to connector clip 160, as shown in FIG. 1B. Further, as shown in FIG. 1B, drain 120d of LS FET die 120 may be positioned directly above source pad (e.g., source pad 110s) of HS FET die 110 (e.g., along vertical axis A-A) separated only by a combined thickness Tc of connector clip 160 and solder layer 122.

As shown in FIG. 1B, the elements of embedded device package 100B as vertically stacked in sequence along a vertical axis A-A, beginning with substrate 102 at the bottom, include a solder layer (e.g., solder layer 112), a first semiconductor die (e.g., HS FET die 110, source pad 110s), a connector clip (e.g., connector clip 160), an adhesive layer (e.g., adhesive layer 132), and a second semiconductor die (e.g., LS FET die 120, drain 120d, gate contact pad 120g).

Another connector clip (e.g., connector clip 170) (e.g., a copper clip) may be attached to LS FET die 120 to connect a source pad (e.g., source pad 110s) of LS FET die 120 to a second connector pad (e.g., connector pad 102c, FIG. 1C) on substrate 102.

The elements of embedded device package 100B as vertically stacked in sequence along a vertical axis B-B, beginning with substrate 102 at the bottom, include, epoxy layer 150 (on left side L of HS FET die 110), connector clip 160, adhesive layer 132, the second semiconductor die (i.e., LS FET die 120, drain 120d, source pad 120s), and connector clip 170.

Further, in embedded device package 100B and embedded device package 100C, a third semiconductor die (e.g., an IC controller chip, controller chip 130) may be disposed at a third vertical level (Level 3) in the z- direction in the packages. Controller chip 130 may be disposed above, and rest on (lay on), a second portion of epoxy layer 150 (e.g., a portion of epoxy layer 150 disposed to, for example, a right side in the x direction (e.g., side R) of HS FET die 110), as shown in FIG. 1B. Controller chip 130 may be disposed on the second portion of epoxy layer 150 in a same processing step or steps that dispose the second semiconductor die (e.g., LS FET die 120) on the first connector clip (e.g., connector clip 160) above the first semiconductor die. Controller chip 130 may be attached to second portion of epoxy layer 150 using an adhesive layer 132. Adhesive layer 132 may include, for example, adhesive epoxy and or wafer back side coating (WBC) materials.

Controller chip 130 (i.e., the signal I/O pads (not shown) of controller chip 130) of may be wire bonded (e.g., using wires 180) to gate contact pads (e.g., gate contact pad 110g of FS FET die 120, gate contact pad 120g of LS FET die 120). The signal I/O pads of controller chip 130 may also be wire bonded (e.g., using wires 180) to one or more pads (e.g., wire bond pad 102w) on substrate 102.

The elements of embedded device package 100B as vertically stacked in sequence along a vertical axis C-C, beginning with substrate 102 at the bottom, include epoxy layer 150 (the second portion of epoxy layer 150 to the right side R of HS FET die 110), adhesive layer 132, controller chip 130, and portions of wires 180.

In example implementations, for automated (or partially automated) assembly line construction of packages (e.g., embedded device package 100B and embedded device package 100C), an array of substrates (e.g., substrate 102) may be supplied (e.g., to an assembly line tool)) on a reeled substrates frame. The array of substrates (e.g., PCB substrates) can be held in the reeled substrates frame between a pair of spaced-apart runner strips with indexing holes. The reeled substrates frame including the array of substrates may be fabricated by plating copper traces and pads (on a PCB sheet).

FIG. 2 shows an example reeled substrates frame 200 including an array (e.g., array 20A) of substrates.

As shown in FIG. 2, substrates frame 200 may include a pair of spaced-apart holed runner strips 200A, 200B. An array 20A of substrates 102 may be held between the spaced-apart holed runner strips. One or both runner strips may include indexing holes 200H to assist in positioning and aligning reeled substrates frame 200 in, for example, assembly line processing tools (e.g., a singulation tool, a die pick-and-place tool, dam-and-fill dielectric fill material injection tools, etc.). Each substrate 102 may include a base carrier portion made of PCB material (e.g., base carrier portion 102b, FIG. 1B), which is plated with copper traces and copper pads including, for example, a landing pad 102l, connector pad 102c, and wire bond pad 102w, etc.

In example implementations, after an embedded device package (e.g., embedded device package 100B, FIG. 1B, or embedded device package 100C, FIG. 1C) is constructed on a substrate 102, components of package may be encapsulated in a molding material, and base carrier portions (e.g., base carrier portion 102b) of the substrate may be removed. Removing the base carrier portions of PCB may leave the plated copper traces and pads (e.g., landing pad 102l, connector pad 102c, and wire bond pad 102w, etc.) held in place by the molding material to serve as external contact terminals for the devices enclosed in embedded device package 100B or embedded device package 100C.

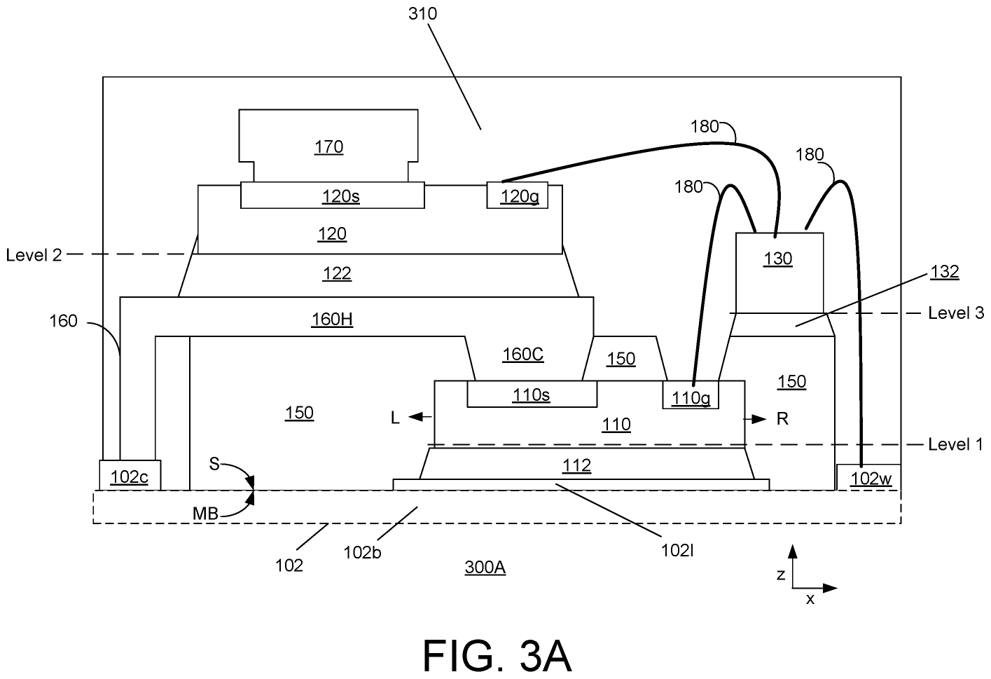

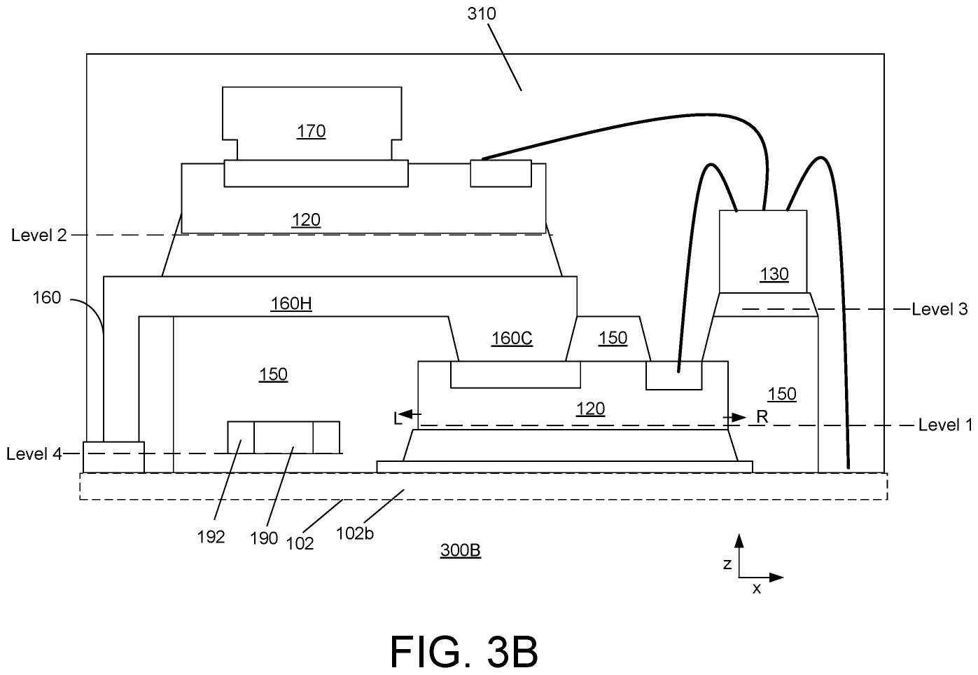

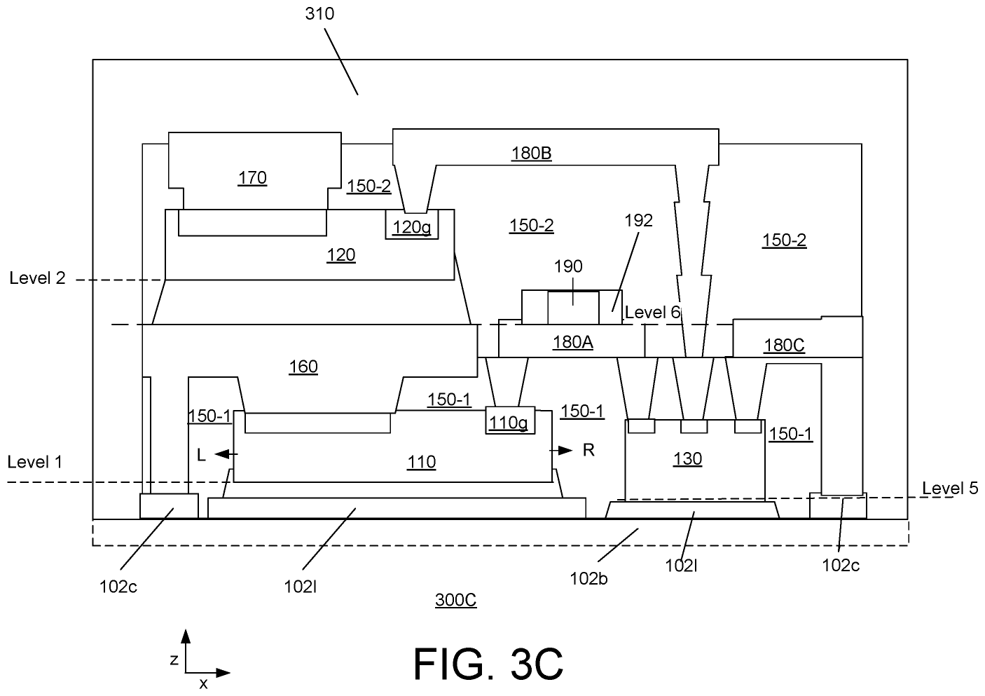

FIG. 3A shows, for example, in cross-sectional view, an embedded device package 300A after removal of the base carrier portions of the substrate on which the embedded device package 300A was constructed.

Embedded device package 300A (like embedded device package 100B or embedded device package 100C) may include multiple semiconductor die (e.g., HS FET die 110, LS FET die 120 and controller chip 130) disposed on planes at different heights or levels (e.g., Level 1, Level 2, and Level 3, respectively) on a substrate (e.g., substrate 102) during construction of the package. Contact pads of the devices (e.g., source and drain contact pads) may be connected by connector clips (e.g., connector clips 160 and 170) and wires (e.g., wires 180) to the plated copper traces and pads (e.g., landing pad 102l, connector pad 102c, and wire bond pad 102w, etc.) on substrate 102. The components of embedded device package 300A may be encapsulated in a molding material (e.g., molding material 310) in a molding step. After the encapsulation, base carrier portion 102b of substrate 102 may be removed. After removal of base carrier portion 102b, pads (e.g., landing pad 102l, connector pad 102c, and wire bond pad 102w, etc.) previously supported by the base carrier portion 102b of substrate 102 may be held in place by the molding material (e.g., molding material 310). The removal of base carrier portion 102b may expose pads (e.g., landing pad 102l, connector pad 102c, and wire bond pad 102w, etc.) as external contacts to the devices encapsulated in molding material 310. These external contacts may be exposed on a bottom surface MB of molding material 310. Bottom surface MB of molding material 310 may correspond to top surface S of the removed base carrier portion 102b of substrate 102. In some example implementations, in addition to FET devices and controller chips (e.g., HS FET die 110, LS FET die 120, and controller chip 130) the embedded device packages constructed using the dam-and-fill technique may include other device components embedded in or disposed on the dam-and-fill dielectric fill material (e.g., epoxy layer 150). The device components may, for example, include a passive device component (e.g., a thin-film redistribution layer (RDL) component).

FIG. 3B shows, for example, another embedded device package 300B after removal of the base carrier portions of the substrate on which the embedded device package 300B was constructed.

Embedded device package 300B (like embedded device package 100B) may include HS FET die 110, LS FET die 120, and controller chip 130 disposed at different levels (e.g., Level 1, Level 2, and Level 3, respectively). Embedded device package 300B may further include a passive device component (e.g., RDL 190). Passive device component RDL 190 may be a thin-film device component with contact pads 192. In example implementations, passive device component RDL 190 may be disposed at a vertical level (e.g., Level 4) on the substrate (e.g., substrate 102) during construction of the package. As shown in FIG. 3B, RDL 190 may be disposed, for example, in epoxy layer 150 on the left side (e.g., side L) of HS FET die 110.

In some example implementations, the device components (e.g., HS FET die 110, LS FET die 120, controller chip 130 and passive device component RDL 190, etc.) in an embedded device package may be disposed, embedded, and interconnected in geometrical configurations or layouts different than the configuration or layout used in embedded device package 300B shown in FIG. 3B.

FIG. 3C shows, for example, another embedded device package 300C after removal of the base carrier portions of the substrate on which embedded device package 300C was constructed.

Embedded device package 300C (like embedded device package 300B) may include HS FET die 110, LS FET die 120, controller chip 130, and a passive device component RDL 190 disposed at different levels on substrate 102 in the package. All of the components (i.e., HS FET die 110, LS FET die 120, controller chip 130, and passive device component RDL 190) may be embedded in dam-and-fill dielectric fill material (e.g., epoxy layer 150-1, or epoxy layer 150-1). In example implementations, HS FET die 110 and LS FET die 120 may be disposed in the package, for example, at Level 1 and Level 2, respectively (like in embedded device package 300B). Controller chip 130 may be disposed, for example, at Level 5 in the package, attached to a landing pad 102l on substrate 102. In example implementations, HS FET die 110 and controller chip 130 may be embedded in a first epoxy layer (e.g., epoxy layer 150-1). Controller chip 130 disposed at Level 5 may be interconnected to gate contact pad 110g of HS FET die 110 using, for example, a connector clip 180A; to gate contact pad 110g of HS FET die 120 using, for example, a connector clip 180B; and to a copper pad (e.g., connector pad 102c) on substrate 102 using, for example, connector clip 180C.

Further, passive device component RDL 190 may be disposed, for example, at a Level 6 in the package. RDL 190 may be disposed on, and connected to, connector clip 180A. In example implementations, RDL 190 may be disposed on connector clip 180A in a same processing step or steps that dispose LS FET die 120 on the first connector clip (e.g., connector clip 160) above HS FET die 110. In example implementations, LS FET die 120 and RDL 190 may be embedded in a second epoxy layer (e.g., epoxy layer 150-2) overlaying the first epoxy layer (e.g., epoxy layer 150-1).

The connector clips (e.g., connector clips 180A, 180B, 180C) may be plated structures (e.g., copper plated structures) formed in embedded device package 300C during construction of the package.

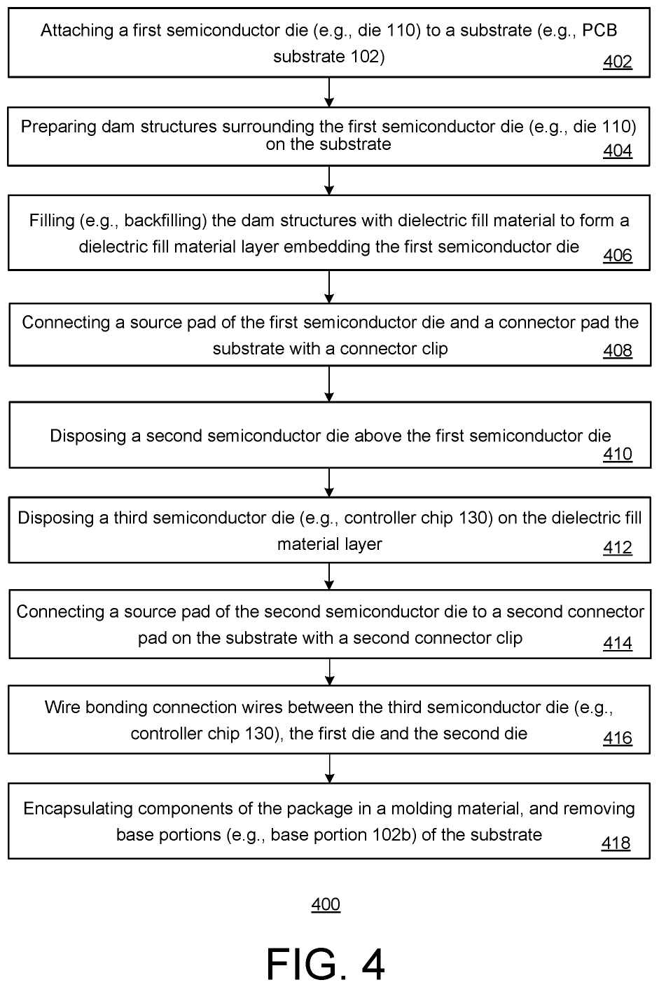

FIG. 4 illustrates an example method 400 for embedding a semiconductor die in an embedded device package.

The embedded device package (e.g., embedded device package 300A, FIG. 3A) may include a plurality of semiconductor die (e.g., HS FET die 110, LS FET die 120, and controller chip 130) disposed during construction of the package at different heights or levels (e.g., Level 1, Level 2, and Level 3, respectively) above a printed circuit board substrate (e.g., substrate 102). Method 400 may involve using dam-and-fill techniques to embed at least a semiconductor die (e.g., HS die 110) in a dam-and-fill dielectric fill material layer (e.g., epoxy layer 150).

Method 400 may include attaching a first semiconductor die (e.g., HS FET die 110) to a substrate (e.g., substrate 102, a PCB substrate) (402), preparing dam structures (e.g., walls and cavities) surrounding the first semiconductor die (e.g., HS FET die 110) on the substrate (404), and filling (e.g., backfilling) the dam structures with dielectric fill material to form a dielectric fill material layer embedding the first semiconductor die (406).

Preparing the dam structures may include dispensing dam-and-fill dielectric fill material to form a dam structure surrounding HS FET die 110, a dam structure surrounding a source pad of HS FET die 110, and a dam structure surrounding a gate contact pad of HS FET die 110. The dam structures may, for example, be walls rising to a vertical height H. The walls may be made by dispensing a lower viscosity dam-and-fill dielectric fill material. Preparing the dam structures may further include filling (backfilling) the dam volumes (i.e., cavities) between the walls of the dam structures with a higher viscosity dam-and-fill dielectric fill material (e.g., to vertical height H). The dielectric fill material-filled dam structures may form the dielectric fill material layer having a vertical height H embedding HS FET die 110.

Method 400 may further include connecting the source pad of the first semiconductor die and a first connector pad on the substrate with a first connector clip (408). The first connector pad may, for example, be on a portion (e.g., an edge) of the substrate external to the dielectric fill material layer. The first connector clip may, for example, be made of copper or other metal or metal alloy. The first connector clip may include a horizontal segment (also can be referred to as a segment) extending horizontally (laterally) from the source pad toward the portion (e.g., an edge) of the substrate external to the dielectric fill material layer surrounding the first semiconductor die. The horizontal segment may contact (e.g., rest on, lay on, extend over) the dielectric fill material layer surrounding the first semiconductor die. The horizontal segment being aligned along a same direction as the substrate 102 (e.g., can be parallel to the substrate 102, aligned along a top surface of the substrate 102).

Method 400 may further include disposing a second semiconductor die above the first semiconductor die (410). Disposing the second semiconductor die (e.g., die 120) above the first semiconductor die may include disposing the second semiconductor die on the horizontal segment of the connector clip. Method 400 may further include disposing a third semiconductor die (e.g., controller chip 130) on the dielectric fill material layer (412). Disposing the third semiconductor die may include disposing the third semiconductor die (e.g., controller chip 130) on a portion of the dielectric fill material layer surrounding the first semiconductor die (e.g., toward or past a right edge R of the first semiconductor die, FIG. 1A). In example implementations, disposing the third semiconductor die on a portion of the dielectric fill material layer may occur in a same processing step or steps that dispose the second semiconductor die on the horizontal segment of the connector clip.

Method 400 may further include connecting the source pad of the second semiconductor die to a second connector pad on the substrate with a second connector clip (414), and wire bonding connection wires between the third semiconductor die (e.g., controller chip 130), the first die, and the second die (416). Wire bonding the connection wires may include wire bonding the connection wires between the third semiconductor die (e.g., controller chip 130) and gate contact pads on the first and second die, and further include wire bonding the connection wires between the third semiconductor die and wire pads on the edge of the substrate.

In some example implementations, method 400 may further include encapsulating components of the package in a molding material and removing base portions of the substrate (418).

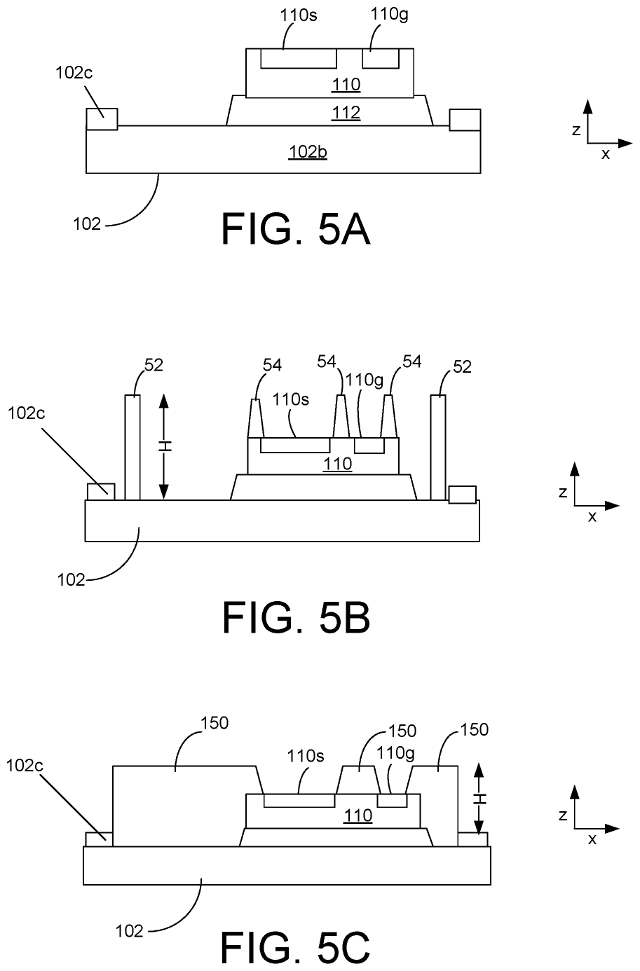

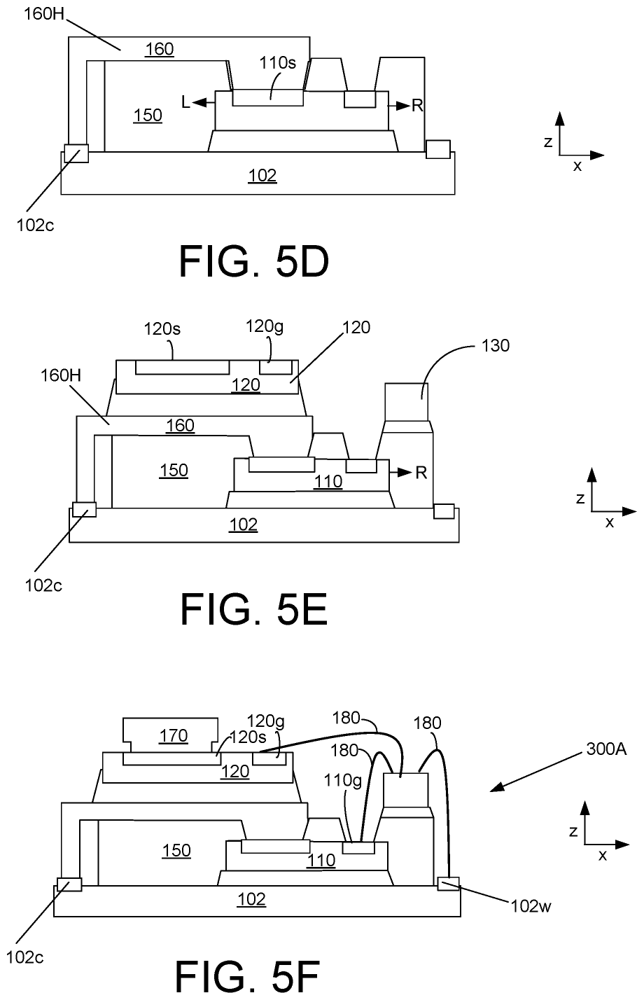

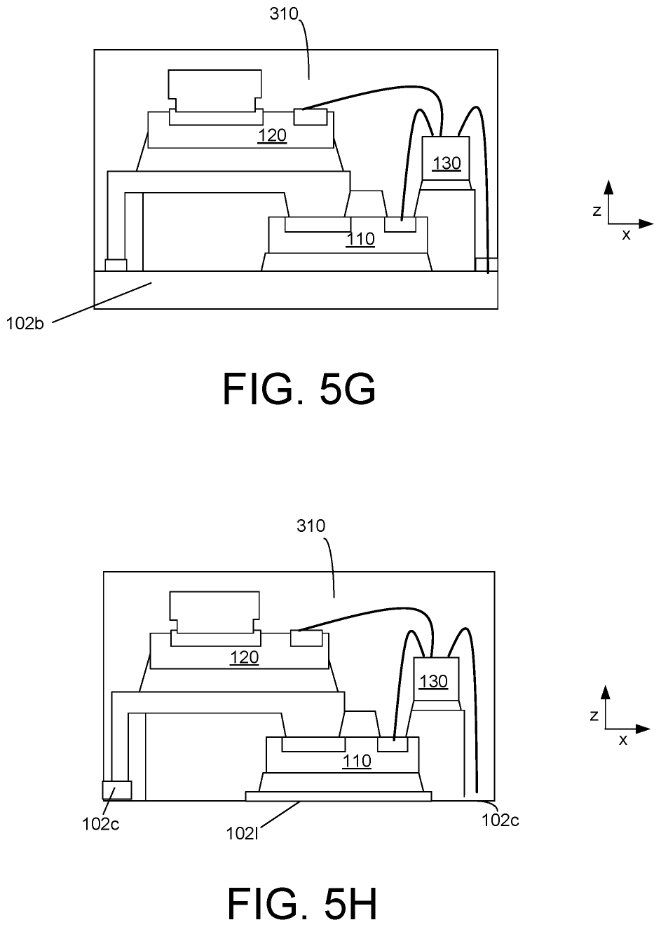

FIGS. 5A-5H show cross-sectional views of an embedded device package (e.g., embedded device package 300A, FIG. 3A) at different stages of construction on a substrate (e.g., substrate 102), or after the different steps of method 400 for embedding a semiconductor die in an embedded device package.

FIG. 5A shows the embedded device package at a first stage of construction (e.g., after method 400, step 402) with a first semiconductor die (e.g., HS FET die 110) attached to substrate 102. The die may be attached to a landing pad on the substrate with a solder layer (e.g., solder layer 112).

FIG. 5B shows the embedded device package at a second stage of construction (e.g., after method 400, step 404) with dams (e.g., vertical walls 52, 54) of vertical height H (formed by the dam-and-fill technique). Vertical walls 52 may, for example, surround the die (e.g., HS FET die 110) attached to the substrate, and vertical walls 54 may, for example, surround source and gate contact pads (e.g., source pad 110s and gate contact pad 110g) on the die.

FIG. 5C shows the embedded device package at a third stage of construction (e.g., after method 400, step 406) with the dams filled (backfilled) between the vertical walls 52 and walls 54 to form an epoxy layer 150 embedding the die (e.g., HS FET die 110) attached to the substrate. Source pad 110s and gate contact pad 110g on the die are not covered by epoxy layer 150 and remain open through epoxy layer 150 for vertical access.

FIG. 5D shows the embedded device package at a fourth stage of construction (e.g., after method 400, step 408) with a first connector clip (e.g., connector clip 160) connecting the source pad (source pad 110s) to a first connector pad (e.g., connector pad 102c) on substrate 102. A horizontal segment 160H of first connector clip (e.g., connector clip 160) may contact (e.g., rest on, lay on, extend over) a portion of epoxy layer 150 to the left (as indicated by the arrow L) of the die (e.g., HS FET die 110) attached to the substrate.

FIG. 5E shows the embedded device package at a fifth stage of construction (e.g., after method 400, step 410 and step 412) with a second semiconductor (e.g., die 120) disposed on horizontal segment 160H of the first connector clip (e.g., connector clip 160) resting on the portion of epoxy layer 150 to the left of the die (e.g., HS FET die 110). FIG. 5E also shows a controller chip (e.g., controller chip 130) disposed on a portion of epoxy layer 150 to the right (as indicated by the arrow R) of the die (e.g., HS FET die 110) attached to the substrate.

FIG. 5F shows the embedded device package at a seventh stage of construction (e.g., after method 400, step 414 and step 416) with a second connector clip (e.g., connector clip 170) attached to connect the source pad (e.g., pad 120s) of the second semiconductor die to a second connector pad (not visible) on the edge of the substrate. FIG. 5F also shows wires 180 interconnecting controller chip 130 to the gate contact pads (e.g., gate contact pad 110g, gate contact pad 120g) of the first and second semiconductor die, and to a wire bond pad (e.g., wire bond pad 102w) on the substrate.

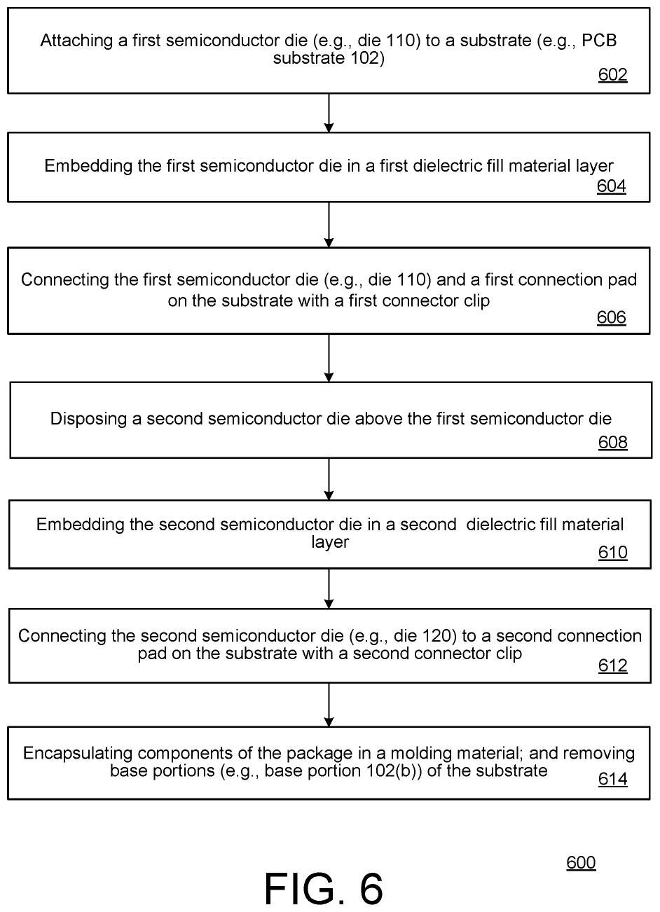

FIGS. 5G and 5H show the embedded device package at an eighth stage of construction (e.g., after method 400, step 418). FIG. 5F shows components of the embedded device package encapsulated in molding material (e.g., molding material 310). FIG. 5G shows the embedded device package with the base carrier portions (e.g., base carrier portion 102b) of the substrate removed. The base carrier portion may be removed, for example, by etching. In the embedded device package, contact pads (e.g., wire bond pad 102w, connector pad 102c, etc.) previously supported by the removed base carrier portions 102b are held in place by molding material 310. FIG. 6 illustrates another example method 600 for embedding a semiconductor die in an embedded device package (e.g., embedded device package 300C, FIG. 3C).

Embedded device package 300C (as shown in FIG. 3C) may include a plurality of semiconductor die (e.g., HS FET die 110 , die 120, and controller chip 130) and passive device components (e.g., RDL 190) disposed at different heights or levels (e.g., Level 1, Level 2, Level 5, and Level 6, respectively) on a printed circuit board substrate (e.g., substrate 102). Method 600 may involve using dam-and-fill techniques to embed semiconductor die (e.g., HS FET die 110 , die 120) in a dam-and-fill dielectric fill material layers (e.g., epoxy layer 150-1, epoxy layer 150-2).

Method 600 may include attaching a first semiconductor die (e.g., HS FET die 110) to a substrate (e.g., substrate 102) (602), and embedding the first semiconductor die in a first dielectric fill material layer (e.g., epoxy layer 150-1) (604).

In method 600, attaching the first semiconductor die 602 may include attaching a further semiconductor die (e.g., controller chip 130) to the substrate. In example implementations, attaching the further semiconductor die (e.g., controller chip 130) to the substrate may occur in a same processing step or steps attaching the first semiconductor die (e.g., HS FET die 110) to the substrate.

In method 600, embedding the first semiconductor die in the first dielectric fill material layer 604 may include preparing dam structures surrounding the first semiconductor die (e.g., HS FET die 110) on the substrate. The dam structures may form the first dielectric fill material layer (e.g., an epoxy layer 150-1) embedding the first semiconductor die. The first dielectric fill material layer may have a first vertical height (i.e., thickness) above the substrate. Embedding the first semiconductor die in the first dielectric fill material layer 604 may also include embedding the further semiconductor die (e.g., controller chip 130) in the first dielectric fill material layer.

Preparing the dam structures may include preparing a dam structure surrounding HS FET die 110, a dam structure surrounding a source pad of HS FET die 110, and a dam structure surrounding a gate contact pad of HS FET die 110, a dam structure surrounding controller chip 130, and dam structures surrounding contact pads on controller chip 130. The dam structures may, for example, may be walls or plugs rising to a vertical height H1 (above the substrate). The walls may be made from viscous dam-and-fill dielectric fill material. The dielectric fill material-filled dam structures may form the first dielectric fill material layer of vertical height H1 embedding HS FET die 110 and controller chip 130. The first dielectric fill material layer may not cover the source pad or the gate contact pad of HS FET die 110, and vias through the first dielectric fill material layer may provide access to contact pads on controller chip 130.

Method 600 may further include connecting the first semiconductor die (e.g., HS FET die 110) and a first connection pad on the substrate with a first connector clip (606). The method may include further interconnecting the first semiconductor die, the controller chip (e.g., controller chip 130), and connections pads on the substrate with additional connector clips.

Method 600 may include plating the first connector clip and the additional connector clips (e.g., copper clips). The plated connector clips may include the first connector clip connecting a source pad of the first semiconductor die to the first connector pad on an edge of the substrate, an additional connector clip connecting a gate contact pad of the first semiconductor die to a first contact pad on the controller chip, a connector clip precursor for connection to a second contact pad on the controller chip, and another additional connector clip connecting a third contact pad on the controller chip to a connector pad on an edge of the substrate. The connector clips (e.g., the first connector clip, and the additional connector clips) may include horizontal segments contacting (e.g., resting on, laying on, extending over) portions of the first dielectric fill material layer surrounding the first semiconductor die and between the first semiconductor die and the controller chip. The connector clip precursor for connection to the second contact pad on the controller chip may be a vertical segment rising through a via in the first dielectric fill material layer from the second contact pad on the controller chip to about a top of the first dielectric fill material layer.

Method 600 may further include disposing a second semiconductor die above the first semiconductor die (608). Disposing the second semiconductor die may further include additionally disposing a passive component (e.g., RDL 190) on the first dielectric fill material layer.

Disposing the second semiconductor die above the first semiconductor die may include attaching the second semiconductor die (e.g., die 120) to the horizontal segment of the first connector clip connecting the source pad of the first semiconductor die to the connector pad on an edge of the substrate. Disposing the passive component (e.g., RDL 190) on the first dielectric fill material layer may include disposing the passive device component (e.g., RDL 190) on the horizontal segment of the additional connector clip connecting the gate contact pad of the first semiconductor die to the first contact pad on the controller chip. In example implementations, RDL 190 may be disposed on the horizontal segment of the additional connector clip in a same processing step or steps that dispose the second semiconductor die above the first semiconductor die.

Method 600 may further include embedding the second semiconductor die in a second dielectric fill material layer (e.g., epoxy layer 150-2) (610). Embedding the second semiconductor die may also include embedding the passive device component (e.g., RDL 190) in the second dielectric fill material layer (e.g., epoxy layer 150-2). The embedding may include preparing further dam structures surrounding the second semiconductor die (e.g., die 120) disposed on the horizontal segment of the first connector clip and further dam structures surrounding the passive device component (e.g., RDL 190) disposed on the horizontal segment of the additional connector clip. The further dam structures may form the second dielectric fill material layer (e.g., a epoxy layer 150-2) embedding the second semiconductor die and the passive device component.

The further dam structures may, for example, be walls or plugs rising to a vertical height H2 (above the substrate). The walls or plugs may be made from a viscous dam-and-fill dielectric fill material. The dielectric fill material-filled dam structures may form the second dielectric fill material layer (having a thickness equal to a difference in vertical heights H2-H1) above the first and second connector clips. The second dielectric fill material layer may not cover the source pad or the gate contact pad of die 120, and a via through the second dielectric fill material layer may provide access to the connector clip precursor for connection to the second contact pad on the controller chip.

Method 600 may further include connecting the second semiconductor die (e.g., die 120) to a second connection pad on the substrate with a second connector clip (612). Method 600 may include interconnecting the second semiconductor die (e.g., die 120) to the controller chip (e.g., controller chip 130) with additional connector clips. The connector clips may be plated connector clips (e.g., copper plated connector clips). The plated connector clips may include connector clips connecting the second semiconductor die (e.g., die 120) to connection pads on the substrate and to the controller chip (e.g., controller chip 130).

The plated connector clips may include, for example, an additional connector clip to connect a source pad of the second semiconductor die to a connector pad on an edge of the substrate, and another additional connector clip to connect the gate contact pad of the second semiconductor die to the connector pad precursor formed in the previous plating step for connection to a second contact pad on the controller chip.

In some example implementations, method 600 may further include encapsulating components of the package in a molding material; and removing base carrier portions (e.g., base portion 102(b)) of the substrate (614).

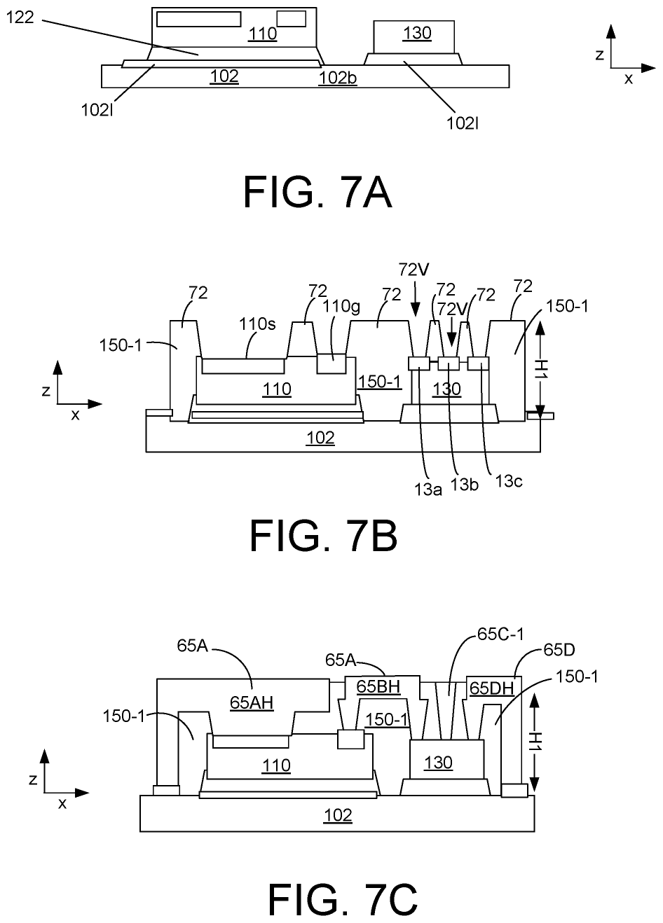

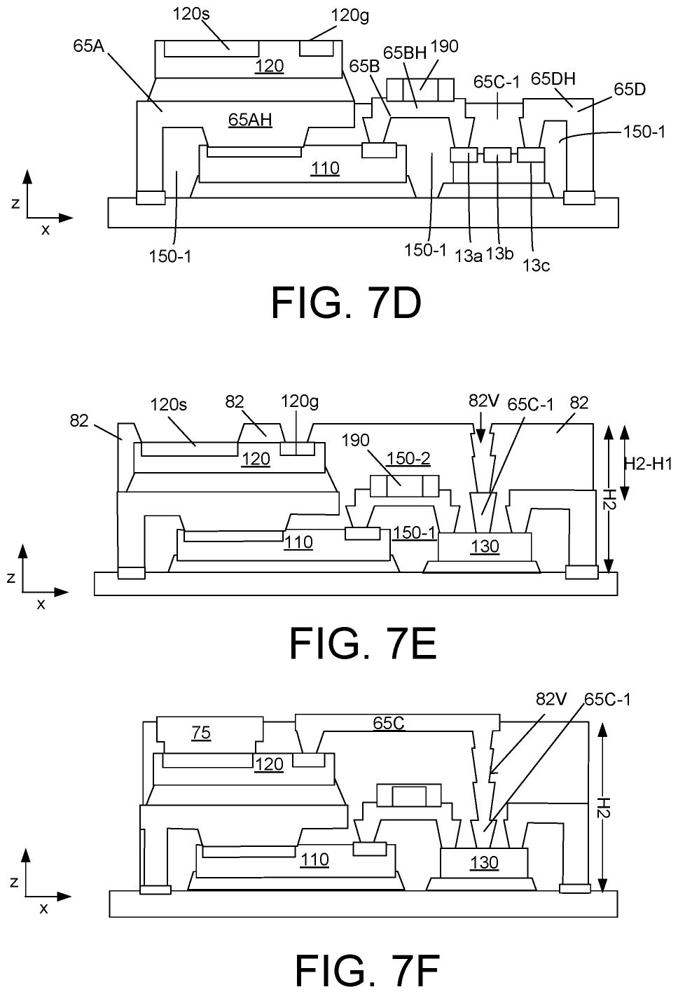

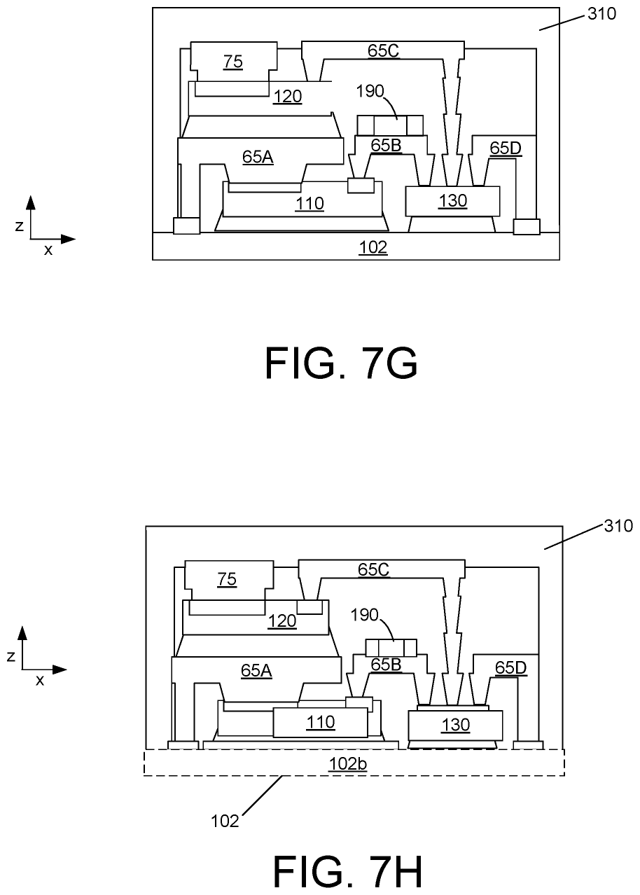

FIGS. 7A-7F show cross-sectional views of embedded device package (e.g., embedded device package 300C, FIG. 3C) at different stages of construction on a substrate (e.g., substrate 102) for example, after the different steps of method 600 for embedding a semiconductor die in an embedded device package.

FIG. 7A shows the embedded device package at a first stage of construction (e.g., after method 600, step 602) with a first semiconductor die (e.g., HS FET die 110) and a controller chip (e.g., controller chip 130) attached to a substrate (e.g., substrate 102). HS FET die 110 and controller chip 130 may be attached to a landing pad (e.g., pad 102l) on the substrate, for example, by a solder layer (e.g., solder layer 122).

FIG. 7B shows the embedded device package at a second stage of construction (e.g., after method 600, step 604) with dam structures (i.e., vertical plugs 72) of vertical height H (formed by the dam-and-fill technique) surrounding the die (e.g., HS FET die 110) attached to the substrate. The dam structures may further include vertical plugs 72 surrounding source and gate contact pads (e.g., source pad 110s and gate contact pad 110g) on the die, and vertical plugs 72 surrounding the controller chip (e.g., controller chip 130). The dam structures form a dielectric fill material layer (e.g., epoxy layer 150-1) in which the die and the controller chip are embedded. Source pad 110s and gate contact pad 110g on the die are not covered by epoxy layer 150-1 and remain open through epoxy layer 150-1 for vertical access. Vias (e.g., laser drilled vias 72V) through the dielectric fill material layer (e.g., epoxy layer 150-1) may provide access to contact pads (e.g., pads 13a, 13b, and 13c) on the controller chip (e.g., controller chip 130).

FIG. 7C shows the embedded device package at a third stage of construction (e.g., after method 600, step 606) with plated connector clips interconnecting the first semiconductor die (e.g., HS FET die 110), the controller chip (e.g., controller chip 130) and connection pads on the substrate (606).

The plated connector clips may include, for example, a first connector clip (e.g., connector clip 65A) interconnecting the source pad of the first semiconductor die to a connector pad on an edge of the substrate, and a second connector clip (e.g., connector clip 65B) interconnecting the gate contact pad of the first semiconductor die to a first contact pad (e.g., pad 13a) on the controller chip (e.g., controller chip 130), a third connector clip precursor (e.g., clip precursor 65C-1) for connection to a second contact pad (e.g., pad 13b) on the controller chip (e.g., controller chip 130), and a fourth connector clip (e.g., connector clip 65D) to connect a third contact pad (e.g., pad 13c) on the controller chip (e.g., controller chip 130) to a connector pad on an edge of the substrate. The first, second and fourth connector clips may include horizontal segment (e.g., horizontal segments 65AH, 65BH and 65DH) contacting (e.g., resting on, laying on, extending over) the dielectric fill material layer (e.g., epoxy layer 150-1) surrounding the first semiconductor die, between the first semiconductor die and the controller chip, and surrounding the controller chip. The third connector clip precursor (e.g., clip precursor 65C-1) for connection to a second contact pad on the controller chip may be a vertical segment or structure rising through a via (e.g., a via 72V) in the dielectric fill material layer from the second contact pad on the controller chip to about a top of the dielectric fill material layer.

FIG. 7D shows the embedded device package at a fourth stage of construction (e.g., after method 600, step 608) with a second semiconductor die (e.g., die 120) disposed above HS FET die 110 on horizontal segment 65AH of first connector clip 65A. FIG. 7D also shows the passive device component (e.g., RDL 190) disposed on horizontal segment 65BH of the second connector clip 65B resting on a portion of epoxy layer 150-1.

FIG. 7E shows the embedded device package at a fifth stage of construction (e.g., after method 600, step 610) with further dam structures 82 surrounding the second semiconductor die (e.g., die 120) disposed on the horizontal segment (e.g., horizontal segment 65AH) of the first connector clip and surrounding the passive device component (e.g., RDL 190) disposed on the horizontal segment (e.g., horizontal segment of the second connector clip. The further dam structures 82 may, for example, be may walls, blocks, or plugs of dielectric fill material rising to a vertical height H2 (above the substrate). Dam structures 82 may be made from viscous dam-and-fill dielectric fill materials. The dielectric fill material-filled dam structures 82 may form an epoxy layer 150-2 (of about vertical height H2-H1 above the first and second connector clips) embedding die 120 and RDL 190. Epoxy layer 150-2 may not cover source pad 120s or gate contact pad 120g of die 120, and a via (e.g., a laser drilled via 82V) through epoxy layer 150-2 may provide access to the previously formed (at the third stage) third connector clip precursor (e.g., clip precursor 65C-1) for connection to the second contact pad (e.g., pad 13b) on the controller chip (e.g., controller chip 130).

FIG. 7F shows the embedded device package at a sixth stage of construction (e.g., after method 600, step 612) with plated connector clips (e.g., connector clips 75 and 65C) interconnecting the second semiconductor die (e.g., die 120) to connection pads on the substrate, and to the controller chip (e.g., controller chip 130).

The plated connector clips may include, for example, a fifth connector clip (e.g., connector clip 75) interconnecting the source pad of the second semiconductor die to a connector pad on an edge of the substrate, and the third connector clip (e.g., connector clip 65C) interconnecting the gate contact pad of the second semiconductor die to the second contact pad (e.g., pad 13b) on the controller chip through via 82V. FIG. 7F also shows that the third connector clip (e.g., connector clip 65C) includes the previously formed third connector clip precursor (e.g., clip precursor 65C-1) for connection to a second contact pad (e.g., pad 13b) on the controller chip (e.g., controller chip 130).

FIGS. 7G and 7H show the embedded device package at a sixth stage of construction (e.g., after method 600, step 614). FIG. 7G shows components of the embedded device package encapsulated in molding material (e.g., molding material 310). FIG. 7H shows the embedded device package with the base carrier portion (e.g., base carrier portions 102b) of the substrate removed. The base carrier portions may be removed, for example, by etching. In the embedded device package, contact pads (e.g., wire bond pad 102w, connector pad 102c, etc.) previously supported on the removed base carrier portions 102b are held in place in the device package by molding material 310.

The methods and dam-and-fill techniques described herein can avoid costly lamination processes for embedding dies. Using LLGA type leadframe as a substrate for embedding dies instead of organic/polymer substrate provides cost advantage. Passive device components can be placed at any level and still be embedded using dam-and-fill material. The embedded device packages have a smaller footprint and may have improved thermal electrical performance for multichip MOSFET power packages.

In example implementations, the epoxy used in the dam-and-fill technique may, for example, be a commercially available epoxy such as NAGASE T693-R5001. The epoxy may be used to form a dam structure with a thickness of up to 4.5 cm and an aspect ratio (i.e., the ratio of the width to the height) in a range of about 1.5:1 to 4:1. The epoxy may have a viscosity in a range of about 500k cps to 1300k cps.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A package comprising:
a dielectric fill material layer embedding a first semiconductor die;
a connector clip having a segment disposed above the dielectric fill material layer embedding the first semiconductor die, the segment being aligned along a same direction as a top surface of the first semiconductor die; and
a second semiconductor die disposed on the segment of the connector clip disposed above the dielectric fill material layer.

2. The package of claim 1, wherein a pad contact element of the connector clip contacts a source pad of the first semiconductor die exposed through the dielectric fill material layer.

3. The package of claim 1, wherein a source pad and a gate contact pad of the first semiconductor die are exposed through the dielectric fill material layer and the connector clip connects the source pad of the first semiconductor die to a first connector pad external to the dielectric fill material layer.

4. The package of claim 3 further comprising, another connector clip connecting a source pad of the second semiconductor die to a second connector pad external to the dielectric fill material layer.

5. The package of claim 1 further comprising, an integrated circuit (IC) controller chip disposed on the dielectric fill material layer.

6. The package of claim 5 further comprising, wire bonds connecting the integrated circuit (IC) controller chip to a gate contact pad of the first semiconductor die and the gate contact pad of the second semiconductor die.

7. The package of claim 1 further comprising, molding material encapsulating the package.

8. The package of claim 1, further comprising, a thin-film redistribution layer (RDL) component disposed in the dielectric fill material layer.

9. A package comprising:
a first semiconductor die;
a second semiconductor die disposed to a side of the first semiconductor die;
a first dielectric fill material layer embedding the first semiconductor die and the second semiconductor die;
a first connector clip having a segment overlaying a first portion the first dielectric fill material layer;
a second connector clip having a segment overlaying a second portion of the first dielectric fill material layer;
a third semiconductor die disposed on the segment of the first connector clip overlaying the first portion of the first dielectric fill material layer; and
a second dielectric fill material layer overlaying the first dielectric fill material layer and embedding the third semiconductor die.

10. The package of claim 9, wherein the first connector clip and the second connector clip are plated connector clips.

11. The package of claim 9, wherein the first connector clip connects a source pad of the first semiconductor die exposed through the first dielectric fill material layer to a first connector pad external to the first dielectric fill material layer.

12. The package of claim 9, wherein the second connector clip connects a gate contact pad of the first semiconductor die exposed through the first dielectric fill material layer to a first signal contact pad of the second semiconductor die.

13. The package of claim 9, further comprising, a thin-film redistribution layer (RDL) component disposed on the segment of the second connector clip and embedded in the second dielectric fill material layer.

14. The package of claim 9, further comprising, a third connector clip connecting a source pad of the third semiconductor die to a second connector pad external to the first dielectric fill material layer and the second dielectric fill material layer.

15. The package of claim 9, further comprising, a fourth connector clip connecting a gate contact pad of the third semiconductor die to a first signal contact pad of the third semiconductor die.

16. The package of claim 9, further comprising, a thin-film redistribution layer (RDL) component disposed on the segment of the second connector clip and embedded in the second dielectric fill material layer.

17. The package of claim 9, wherein at least one of a gate contact pad of the first semiconductor die, and a first signal contact pad and a second signal contact pad of the second semiconductor die are exposed through the first dielectric fill material layer by vias drilled through the first dielectric fill material layer, and wherein at least one of a gate contact pad of the third semiconductor die and the second signal contact pad of second semiconductor die are exposed through the second dielectric fill material layer by vias drilled through the second dielectric fill material layer.

18. The package of claim 9, further comprising, a molding material encapsulating components of the package.

19. A method for embedding semiconductor dies in an embedded device package, the method comprising:
attaching a first semiconductor die to a substrate;
embedding the first semiconductor die in a dielectric fill material layer;
connecting a source pad of the first semiconductor die and a first connector pad on the substrate with a first connector clip, the first connector clip including a segment extending from the source pad toward a portion of the substrate external to the dielectric fill material layer embedding the first semiconductor die;
disposing a second semiconductor die on the first connector clip above the first semiconductor die;
disposing a third semiconductor die on the dielectric fill material layer;
connecting a source pad of the second semiconductor die to a second connector pad on the portion of the substrate external to the dielectric fill material layer with a second connector clip;
wire bonding connection wires between the third semiconductor die and gate contact pads on the first semiconductor die and the second semiconductor die; and
encapsulating components of the embedded device package in a molding material.

20. The method of claim 19, wherein encapsulating components of the embedded device package in a molding material includes:
removing to a substrate.

21. The method of claim 19, wherein embedding the first semiconductor die in the dielectric fill material layer includes:
dispensing dam-and-fill dielectric fill material to form a first dam structure surrounding the first semiconductor die, a second dam structure surrounding the source pad of the first semiconductor die, and a third dam structure surrounding a gate contact pad of the first semiconductor die, the first dam structure, the second dam structure, and the third dam structure including walls that have vertical heights; and
dispensing dam-and-fill dielectric fill material to backfill the first dam structure, the second dam structure, and the third dam structure to their vertical heights to form the dielectric fill material layer embedding the first semiconductor die.

22. A method for embedding semiconductor die in an embedded device package, the method comprising:
attaching a first semiconductor die to a substrate;
embedding the first semiconductor die in a first dielectric fill material layer;
connecting the first semiconductor die and a first connection pad on the substrate with a first connector clip;
disposing a second semiconductor die on the first connector clip above the first semiconductor die;
embedding the second semiconductor die in a second dielectric fill material layer overlaying the first dielectric fill material layer;
connecting the second semiconductor die to a second connection pad on the substrate with a second connector clip; and
encapsulating components of the embedded device package in a molding material.

23. The method of claim 22, wherein embedding the first semiconductor die in the first dielectric fill material layer includes:
preparing dam structures surrounding the first semiconductor die on the substrate, the dam structures forming the first dielectric fill material layer;
wherein connecting the first semiconductor die and the first connection pad on the substrate with the first connector clip includes plating to form the first connector clip.

24. The method of claim 22, wherein embedding the second semiconductor die in the second dielectric fill material layer includes:
preparing further dam structures surrounding the second semiconductor die disposed on the first connector clip above the first semiconductor die, the further dam structures forming the second dielectric fill material layer;
wherein connecting the second semiconductor to a second connection pad on the substrate with the second connector clip includes plating to form the second connector clip.
